(19) United States
(12) Patent Application Publication
(10) Pub. No.: US 2025/0364934 A1
(43) Pub. Date: Nov. 27, 2025

(54) NON-CONTACT CONTROL ASSEMBLY FOR CONTROLLING OPERATION OF ELECTRICAL DEVICE

(71) Applicant: DEFOND ELECTECH CO., LTD, Dongguan (CN)

(72) Inventors: Cheng Chen NIEH, Dongguan (CN); Chiu Keung LOONG, Dongguan (CN); Wai Man WONG, Dongguan (CN); Ka Wai LAU, Dongguan (CN)

(73) Assignee: DEFOND ELECTECH CO., LTD, Dongguan (CN)

(21) Appl. No.: 18/926,023

(22) Filed: Oct. 24, 2024

(30) Foreign Application Priority Data
May 27, 2024 (CN) 2024106710879

(51) Int. Cl. H02P 23/14; G01D 5/14; G01D 5/16; G01D 5/34; H02P 23/20

(52) U.S. Cl. CPC H02P 23/14; G01D 5/142; G01D 5/16; G01D 5/34; H02P 23/20

(57) ABSTRACT

The present application relates to a non-contact control assembly using a magnetic sensor, including a control assembly housing; a magnetic sensor; a magnetic element; an actuator; a connection port, for establishing a power and signal connection with a motor control module; and a magnetic shielding shell, operably connected to the actuator, and the magnetic element being mounted to the actuator and located in the magnetic shielding shell. The magnetic shielding shell includes a three-dimensional closed loop structure having two open surfaces, in response to the movement of the actuator relative to the control assembly housing, the magnetic sensor is able to enter an interior of the magnetic shielding shell through one of the open surfaces of the magnetic shielding shell and move towards the other of the open surfaces of the magnetic shielding shell relative to the magnetic element in the interior of the magnetic shielding shell.

### RELATED APPLICATIONS

The present patent document claims the benefit of priority to Patent Application No. CN 2024106710879, filed May 27, 2024, and entitled “NON-CONTACT CONTROL ASSEMBLY FOR CONTROLLING OPERATION OF ELECTRICAL DEVICE” the entire contents of which are incorporated herein by reference.

### BACKGROUND

### 1. Technical Field

The present application relates to a non-contact potentiometer speed regulation switch for realizing operation of electrical devices such as an electric tool, and in particular, to a non-contact control assembly which uses a magnetic sensor (such as a linear Hall effect sensor or a magnetoresistive effect sensor) to regulate a speed and has a function of shielding external magnetic interference.

### 2. Background Information

Conventional speed control in electric tools typically relies on a variable voltage transformer called a potentiometer, and the resistor utilizes a carbon film on a circuit board. However, repeated sliding contact of an electric brush on the carbon film will cause severe wear, resulting in inaccurate speed regulation. In addition, the carbon film is prone to contamination, increasing the risk of short circuit and further damage.

In order to minimize the physical wear of the electric brush and the carbon film, the prior art already has a non-contact control switch using a Hall sensor. However, the use of such non-contact control switch generally faces the problem of external magnetic signal source interference. When these devices are subjected to magnetic interference, it may lead to misoperation, causing the devices to start or stop without warning, increasing operation risks; reduced control accuracy, unstable output of the Hall sensor affecting the operation speed or steering control of the electric tools; decreased reliability, frequent magnetic interference accelerating mechanical wear and shortening device life; and potential safety risks, especially in application scenarios having high-precision or greatly high safety requirements, such as medical devices or precision manufacturing, sensor misreading caused by magnetic interference may cause serious safety accidents. External magnetic interference may cause unstable or degraded performance of the electric tools during use. If the non-contact switch is used instead of electrical switch functions, there is also a risk of accidental operation of a motor under external magnetic interference. Therefore, solving the problem of external magnetic signal source interference is crucial for improving the performance and safety of the non-contact control switch. By improving magnetic shielding technology, these negative effects can be effectively reduced, ensuring the precision and reliability of device operation.

The prior art 1 discloses a Hall speed regulation signal switch, which uses an outer shielding cover 210 to solve the problem of external magnetic interference, as shown in FIG. 1A. In order to evaluate the influence of external magnetic interference on the signal switch, the applicant conducted detailed magnetic interference testing. The influence of externally applying different degrees of magnetic interference on an output voltage when the relative position output between a magnet and a Hall element is 50% of the maximum output without external interference magnetic flux is simulated. In testing, the applicant will use a magnetic field generator to increase the magnetic flux from zero to approximately 70 milliTesla and observe a switch output voltage that increases from 50% to 75% of an input voltage. As a result, as shown by curve A in FIG. 2, when a high magnetic flux is applied, the output voltage of the switch changes significantly, showing that the internal Hall sensor and the magnetic element are interfered by an external magnetic flux. These findings confirm that this patent still has room for improvement in protection against external magnetic interference. Based on the above result, the outer shielding cover 210 cannot effectively shield external magnetic interference, and may also affect the speed control precision of the sensor. In addition, external design requires an additional space, limiting the flexibility of application program design. Furthermore, the outer shielding cover 210 needs to use more magnetic shield materials and has a larger volume, and there are many and relatively complex processes for producing the shielding cover.

The prior art 2 discloses a non-contact speed regulation switch, assembled with two permanent magnets 220 respectively arranged at two sides of a Hall element 230, and magnetic poles of the two permanent magnets 220 are respectively a south pole and a north pole and are arranged oppositely. As shown in FIG. 1B, this patent considers that the two permanent magnets 220 can form a stable magnetic field region. In order to evaluate the influence of external magnetic interference on the speed regulation switch, the applicant conducted detailed magnetic interference testing. The influence of externally applying different degrees of magnetic interference on an output voltage when the relative position output between a magnet and a Hall element is 50% of the maximum output without external interference magnetic flux is simulated. In testing, the applicant will use a magnetic field generator to increase the magnetic flux from zero to approximately 70 milliTesla and observe a switch output voltage that increases from 50% to 77% of an input voltage. As a result, as shown by curve B in FIG. 2, when a high magnetic flux is applied, the output voltage of the switch changes significantly, showing that the internal Hall element 230 and the permanent magnets 220 are seriously interfered. These findings confirm that this patent still has room for improvement in protection against external magnetic interference. In addition, the design of the two permanent magnets requires additional materials, bulk, and space.

The prior art 3 describes a non-contact potentiometer signal switch, configured with two magnetic steels 240. The magnetic steels 240 are horizontally disposed beside a speed regulation push rod and have a south pole and a north pole. The speed regulation push rod drives an N-pole magnetic steel and an S-pole magnetic steel to also form linear reciprocating movement relative to a linear Hall element 250. As shown in FIG. 1C, the purpose of this patent is to avoid affecting the stability and consistency of an output rotational speed and power of a motor. To validate the above conclusion, the applicant conducted detailed magnetic interference testing. The influence of externally applying different degrees of magnetic interference on an output voltage when the relative position output between a magnet and a Hall element is 50% of the maximum output without external interference magnetic flux is simulated. In testing, the applicant will use a magnetic field generator to increase the magnetic flux from zero to approximately 70 milliTesla and observe a switch output voltage that increases from 50% to 68% of an input voltage. As a result, as shown by curve C in FIG. 2, when a high magnetic flux is applied, the output voltage of the switch changes significantly, showing that the internal Hall element 250 and the magnetic steels 240 are seriously interfered. These findings confirm that this patent still has room for improvement in protection against external magnetic interference.

In order to evaluate the influence of external magnetic interference on the operation of the signal switch, the applicant firstly measured a correlation between an output voltage and an actuator stroke in a state of no magnetic interference. 3.3 volts is used as an example voltage of the test (an output voltage display form in FIG. 3A-FIG. 3B is displayed in a maximum output voltage percentage), and as shown in FIG. 3A, the voltage rapidly rises from approximately 0% of the maximum output voltage to approximately 40% of the maximum output voltage, then has a significantly slowed increase between 40% and 60% of the maximum output voltage, and then rapidly rises from 60% of the maximum output voltage to the maximum output voltage. The test result shows that due to the use of the two separate magnetic steels 240, the voltage output by the linear Hall element 250 exhibits a significant non-linear change. If the non-linear or non-uniform distribution of the voltage is applied to the electric tools, the voltage change thereof may significantly affect tool performance, especially in scenarios requiring precise control. The voltage change fluctuation directly influences the consistency between speed and torque of the motor, which may cause imprecise operation, increasing the use risk. Therefore, the voltage change fluctuation problem shall be improved or avoided as far as possible, so as to ensure the stability of tools (such as an electric tool) and safety in operation.

The applicant further conducted an external magnetic interference test, and a specific method is applying a high magnetic flux magnet (approximately 210 milliTesla) externally to the device as a magnetic interference source. The test result is presented in the form of a carve graph, as shown in FIG. 3B, the solid line represents an output voltage without the influence of the external magnetic flux, and the dashed line represents an output voltage with the influence of the external magnetic interference source. The graph shows that under the influence of external magnet interference, the output voltage is significantly changed. For example, when the stroke of the speed regulation push rod is approximately 5 millimeters, the output voltage shall be 52% of the input voltage, but under magnetic interference, the output voltage suddenly becomes approximately 78%, such a significant change will cause the speed of the electric tool to suddenly increase substantially, which may pose a danger to a user. In addition, the stroke in which the output voltage starts to rise and the stroke in which the output voltage saturates are also influenced. This proves that this patent still has room for improvement in protection against external magnetic interference, which may affect the operation stability or performance of the electric tool.

The electrical switch in the prior art also uses an internal magnetic shielding shell to solve the problem of external magnetic interference, for example, the prior art 4 discloses a control assembly for controlling an operation speed or torque of an electric device, including a control assembly housing, a magnetic sensor 260, a magnetic element 270, an actuator 280, a control module and a magnetic shielding element 290, the magnetic shielding element 290 is positioned in the control assembly housing to relieve interference of an external magnetic signal source of the control assembly with sensing of the magnetic sensor, and the magnetic shielding element 290 includes a three-dimensional closed loop structure having an open surface through which an interior of the magnetic shielding element 290 may be entered, as shown in FIG. 1D. However, this patent also has the following limitation that: 1. the magnetic sensor 260 must be aligned directly with the magnetic element 270. When the magnetic element 270 is far away from the magnetic sensor 260, an output voltage of the magnetic sensor 260 may decrease; and when the magnetic element 270 is close to the magnetic sensor 260, the output voltage of the magnetic sensor 260 may increase. This limits that the magnetic sensor 260 must be disposed at a position farther from the magnetic element 270, requiring a larger spacing than that in the present invention, resulting in an increased size of the control assembly, making it difficult to make a more compact switch with a shorter length and longer stroke. 2. In addition, since a larger spacing is required, the magnetic element 270 must have a higher magnetic flux to activate the output of the magnetic sensor 260, the volume and cost of the magnetic element 270 are relatively increased over the present invention. 3. In order to effectively prevent magnetic interference, since the magnetic sensor is located at an end of the magnetic shielding element 290 and may be subjected to risks of interference from external magnetic flux, the magnetic shielding element 290 needs to be protected using one end closed. However, such a magnetic shielding element 290 having one end closed increases manufacturing costs and increases the overall length required and presents manufacturing challenges.

### BRIEF SUMMARY

The present application aims to mitigate at least one of the above problems.

The present application may include several generalized forms. Embodiments of the present application may include one or any combination of the different generalized forms described herein.

In one generalized form, the present application provides a non-contact control assembly for controlling operation of an electrical device, including:

a control assembly housing;

a magnetic sensor;

a magnetic element;

an actuator, configured to move relative to the control assembly housing, wherein in response to movement of the actuator relative to the control assembly housing, the magnetic sensor and the magnetic element move relative to each other between at least one of a first position and a second position, so that the magnetic sensor senses a first magnetic field reading when at the first position and senses a second magnetic field reading when at the second position;

a connection port, for establishing a power and signal connection with a motor control module, wherein the motor control module is operably connected to the magnetic sensor and configured for controlling, by referring to output of the magnetic sensor indicating a sensed first magnetic field reading and a sensed second magnetic field reading, respectively, the electrical device to operate at at least one of a first speed or torque and a second speed or torque; and

a magnetic shielding shell, operably connected to the actuator, and the magnetic element being mounted to the actuator and located in the magnetic shielding shell, wherein the magnetic shielding shell includes a three-dimensional closed loop structure having two open surfaces, in response to the movement of the actuator relative to the control assembly housing, the magnetic sensor is able to enter an interior of the magnetic shielding shell through one of the open surfaces of the magnetic shielding shell and move towards the other of the open surfaces of the magnetic shielding shell relative to the magnetic element in the interior of the magnetic shielding shell, so as to effectively eliminate interference of an external magnetic signal source of the non-contact control assembly with sensing by the magnetic sensor on the first magnetic field reading and the second magnetic field reading produced by the magnetic element in response to the movement of the actuator.

Preferably, the magnetic sensor includes a linear Hall effect sensor or a magnetoresistive effect sensor.

Preferably, the non-contact control assembly further includes a connection member, and the connection member is constructed for establishing a telecommunication connection between the magnetic sensor and the motor control module.

Preferably, the connection member includes a sensor PCB, the magnetic sensor is mounted to the sensor PCB, and the non-contact control assembly further includes a main PCB that is operably connected to the sensor PCB.

Preferably, the sensor PCB is a flexible PCB, one end of the flexible PCB is connected to one end of the main PCB, the other end of the flexible PCB is separated from the other end of the main PCB to form a gap, the gap is constructed for a sidewall of the magnetic shielding shell to move via the gap, such that the magnetic sensor enters the interior of the magnetic shielding shell along with the flexible PCB through one of the open surfaces of the magnetic shielding shell and moves towards the other of the open surfaces of the magnetic shielding shell relative to the magnetic element in the interior of the magnetic shielding shell.

Typically, the non-contact control assembly further includes a support member for supporting the flexible PCB, the support member is mounted inside the control assembly housing, and at least a portion of the support member is connected to the other end of the flexible PCB.

Further preferably, the sensor PCB is a rigid PCB, one end of the rigid PCB is connected to one end of the main PCB, the other end of the rigid PCB is separated from the other end of the main PCB to form a gap, the gap is constructed for a sidewall of the magnetic shielding shell to move via the gap, such that the magnetic sensor enters the interior of the magnetic shielding shell along with the rigid PCB through one of the open surfaces of the magnetic shielding shell and moves towards the other of the open surfaces of the magnetic shielding shell relative to the magnetic element in the interior of the magnetic shielding shell.

Preferably, one end of the rigid PCB is connected to one end of the main PCB as a whole.

Preferably, the non-contact control assembly is integrally formed in a contact electrical switch, the contact electrical switch includes at least one pair of electrical switch contacts, and the actuator includes a contact actuation member for closing or opening the electrical switch contacts. The contact actuation member of the actuator may operate one or more pairs of electrical switch contacts, and the electrical switch contacts may be configured to be normally open and/or normally closed.

Further preferably, the non-contact control assembly is integrally formed in a non-contact electrical switch, the non-contact electrical switch includes at least one contactless switching device, and in response to the movement of the actuator relative to the control assembly housing, the contactless switching device is constructed to be closed or opened.

Preferably, the output of the magnetic sensor includes variable voltage, variable resistance or digital output, to indicate at least one of the sensed first magnetic field reading and the sensed second magnetic field reading.

Preferably, an operation speed or torque of the electrical device includes an operation speed or torque of a motor of the electrical device.

Preferably, the non-contact control assembly further includes:

an optical sensor;

a shielding element; and

a commutation member, configured to move relative to the control assembly housing, wherein in response to movement of the commutation member relative to the control assembly housing, when the commutation member moves to different positions relative to the control assembly housing, the optical sensor is used for sensing changes in light reception at the different positions,

wherein the motor control module is operably connected to the optical sensor and is configured for controlling, by referring to the changes in the light reception output by the optical sensor, the electrical device to operate in any one of a forward operation mode and a reverse operation mode.

Preferably, the optical sensor includes a photointerrupter.

Preferably, the optical sensor is mounted into the control assembly housing and the shielding element is mounted to the commutation member.

Preferably, forward operation and reverse operation of the electrical device include forward operation and reverse operation of a motor of the electrical device.

Preferably, the electrical device includes at least one of an electric tool and an electric gardening tool.

In another generalized form, the present application provides an electrical switch, including the above non-contact control assembly.

### BRIEF DESCRIPTION OF THE DRAWINGS

Through the following detailed description of preferred but non-limiting embodiments described in conjunction with accompanying drawings, the present application will be more fully understood, where

FIG. 1A-FIG. 1C show perspective views of electrical switches in prior arts 1-3, respectively;

FIG. 1D shows a sectional view of a control assembly in prior art 4, shielding external magnetic interference by using an internal magnetic shielding shell;

FIG. 2 shows simulating an influence of externally applying different degrees of magnetic interference on an output voltage of an electrical switch when a relative position output between a magnet and a Hall element is 50% of a maximum output without external interference magnetic flux in prior arts, wherein curves A, B and C represent the prior arts 1-3, respectively;

FIG. 3A-FIG. 3B show a correlation between an output voltage of the electrical switch and an actuator stroke in the prior art 3, respectively, wherein FIG. 3A shows an output voltage without an influence of an external magnetic flux, and in FIG. 3B, a solid line represents an output voltage without the influence of the external magnetic flux, and a dashed line represents an output voltage with an influence of an external magnetic interference source;

FIG. 4A-FIG. 4C show a perspective view, an exploded view and a side sectional view of an electrical switch including a non-contact control assembly according to a first embodiment of the present application, respectively, wherein a trigger is pressed by a finger of a user so that an actuator moves inwards from position OFF to position ON relative to an opening of a control assembly housing; and when the trigger is released by the finger of the user, the actuator is prompted by a return spring to move outwards from the position ON to the position OFF relative to the opening of the control assembly housing;

FIG. 5A-FIG. 5B show an exploded view before assembly and a perspective view after assembly of a brake, a magnetic shielding shell and a magnetic element according to the first embodiment of the present application, respectively, wherein the magnetic shielding shell is configured to be positioned on the actuator, and the magnetic element is configured to be positioned on one side inside the magnetic shielding shell and to be fixed together on the actuator;

FIG. 6A-FIG. 6B show an exploded view before assembly and a perspective view after assembly of a magnetic sensor (such as a linear Hall effect sensor) and a connection member according to the first embodiment of the present application, respectively, wherein the connection member includes a sensor PCB, the sensor PCB is a flexible PCB, and the connection member further includes a support member for supporting the flexible PCB;

FIG. 7 shows an assembly perspective view of the magnetic element, the magnetic sensor (such as the linear Hall effect sensor) and the magnetic shielding shell according to the first embodiment of the present application, wherein the magnetic sensor enters an interior of the magnetic shielding shell along with the flexible PCB through one of open surfaces of the magnetic shielding shell and moves towards the other of the open surfaces of the magnetic shielding shell relative to the magnetic element in the interior of the magnetic shielding shell;

FIG. 8A-FIG. 8C show sectional views of the magnetic element when moving to different positions relative to the magnetic sensor (such as the linear Hall effect sensor) according to the first embodiment of the present application, respectively, wherein FIG. 8A shows that an output voltage of the magnetic sensor is zero volt when at an S pole of a magnet; FIG. 8B shows that the output voltage of the magnetic sensor is close to half of an input voltage when between two poles of the magnet; and FIG. 8C shows that the output voltage of the magnetic sensor is equal to the input voltage when at an N pole of the magnet;

FIG. 9A-FIG. 9B show a perspective view and an exploded view of an electrical switch including a non-contact control assembly according to a second embodiment of the present application, respectively, wherein a trigger is pressed by a finger of a user so that an actuator moves inwards from position OFF to position ON relative to an opening of a control assembly housing; and when the trigger is released by the finger of the user, the actuator is prompted by a return spring to move outwards from the position ON to the position OFF relative to the opening of the control assembly housing;

FIG. 10A-FIG. 10B show an exploded view before assembly and a perspective view after assembly of a brake, a magnetic shielding shell and a magnetic element according to the second embodiment of the present application, respectively, wherein the magnetic shielding shell is configured to be positioned on the actuator, and the magnetic element is configured to be positioned on one side inside the magnetic shielding shell;

FIG. 11A-FIG. 11B show perspective views before and after assembly of the magnetic element, a magnetic sensor (such as a linear Hall effect sensor) and the magnetic shielding shell according to the second embodiment of the present application, wherein the magnetic sensor enters an interior of the magnetic shielding shell along with a rigid PCB through one of open surfaces of the magnetic shielding shell and moves towards the other of the open surfaces of the magnetic shielding shell relative to the magnetic element in the interior of the magnetic shielding shell;

FIG. 12A-FIG. 12B show state views of electrical switch contacts according to the first or second embodiment of the present application, wherein FIG. 12A is a state view of the electrical switch contacts being opened when the actuator is in an initial state, and FIG. 12B is a state view of the electrical switch contacts being closed when the actuator is pushed;

FIG. 13A shows a perspective view of an electrical switch including a non-contact control assembly according to a fourth embodiment of the present application, wherein an optical sensor includes a first optical sensor and a second optical sensor, a commutation member includes a sliding member, a shielding element is fixed to a top of the sliding member, and when the sliding member moves to a rightward position, the shielding element is constructed for shielding a gap of the first optical sensor; and when the sliding member moves to a leftward position, the shielding element is constructed for shielding a gap of the second optical sensor;

FIG. 13B-FIG. 13C show perspective views of the optical sensor and the shielding element according to the fourth embodiment of the present application, respectively, wherein the optical sensor is mounted on a main PCB, and the shielding element is fixed to the top of the sliding member, where FIG. 13B shows the sliding member, while FIG. 13C omits the sliding member;

FIG. 14 shows a voltage change curve graph in an ideal state of the magnetic element when moving to different positions relative to the magnetic sensor (such as the linear Hall effect sensor) according to the present application, (such as an input voltage of 3.3 V) wherein prior to position A to position A, the output voltage of the magnetic sensor is zero volt; at position B, the output voltage of the magnetic sensor is 1.65 V, which is half of the input voltage; and at position C to post position C, the output voltage of the magnetic sensor is 3.3 V, which is equal to the input voltage. Depending on working voltages of circuits and devices, the input voltage of the magnetic sensor may be other voltages, such as 5.0 V;

FIG. 15 shows a curve graph of a thickness of a shielding layer and an external magnetic field intensity exposed to the magnetic sensor (such as the linear Hall effect sensor) according to the present application, wherein a magnetic induction intensity curve represents a maximum magnetic induction intensity value acceptable around the switch;

FIG. 16A-FIG. 16C show control circuit diagrams of the electrical switch including the non-contact control assembly according to first, third, and fourth embodiments of the present application;

FIG. 17 shows an influence of the electrical switch including the non-contact control assembly on the output voltage under external magnetic interference according to the present application, wherein a dashed line represents having no magnetic shielding shell, and a solid line represents having a magnetic shielding shell;

FIG. 18A-FIG. 18C show a correlation between the output voltage of the electrical switch including the non-contact control assembly and an actuator stroke according to the present application, respectively, wherein FIG. 18A shows an output voltage without an influence of an external magnetic flux, FIG. 18B shows an output voltage with an influence of an external magnetic interference source; and FIG. 18C shows combination of FIG. 18A and FIG. 18B.

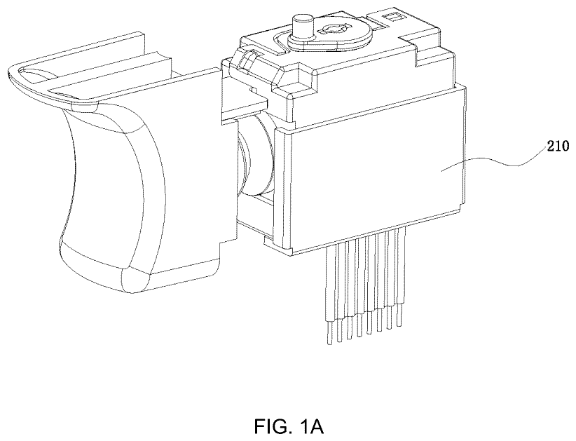

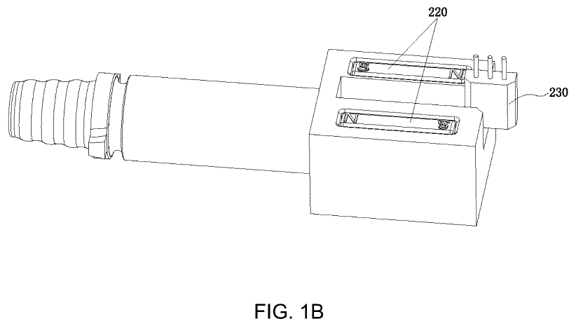

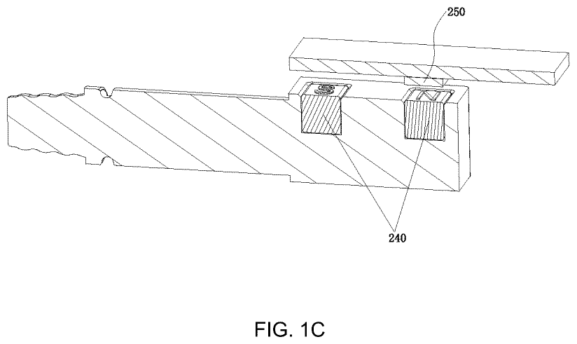

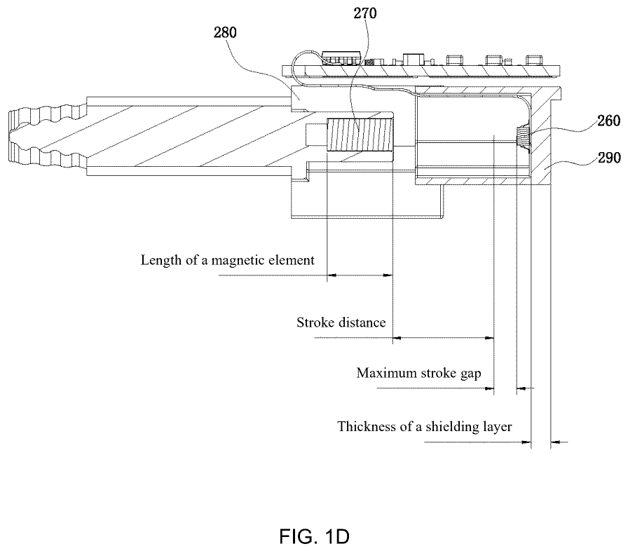

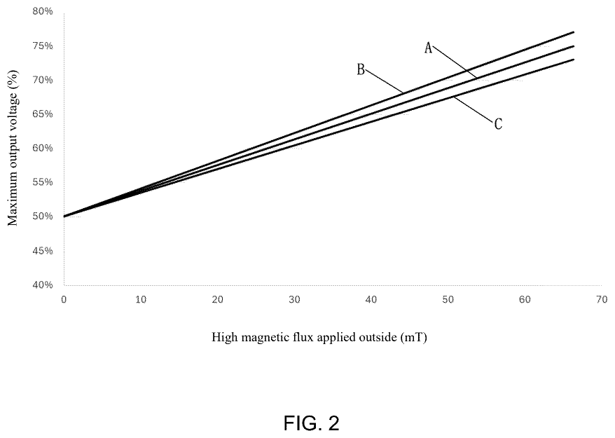

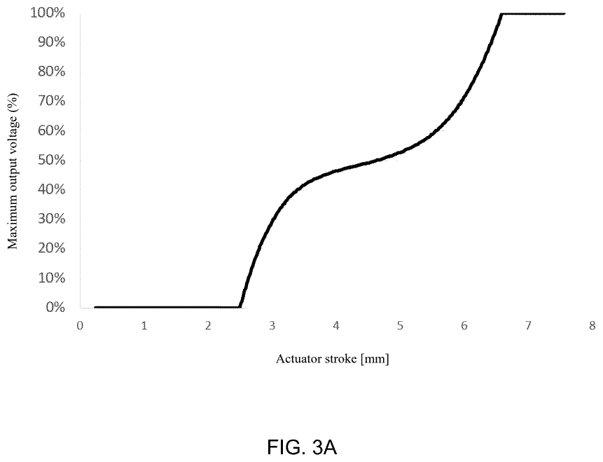

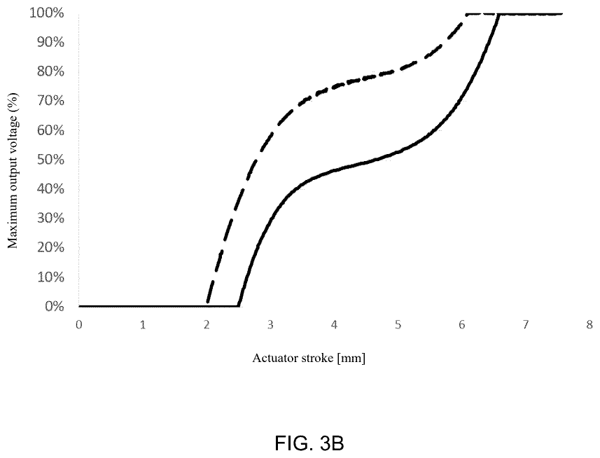

### DETAILED DESCRIPTION OF THE DRAWINGS AND THE PRESENTLY PREFERRED EMBODIMENTS

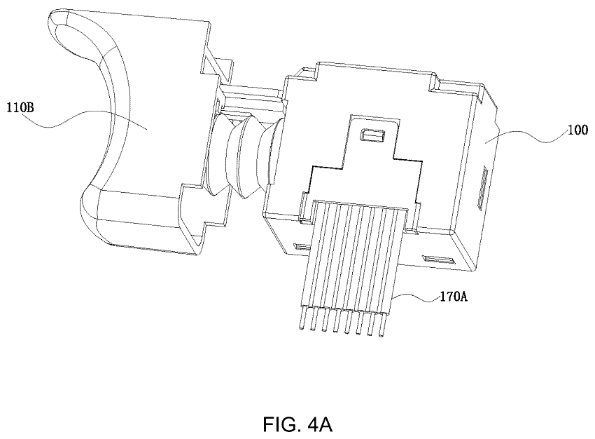

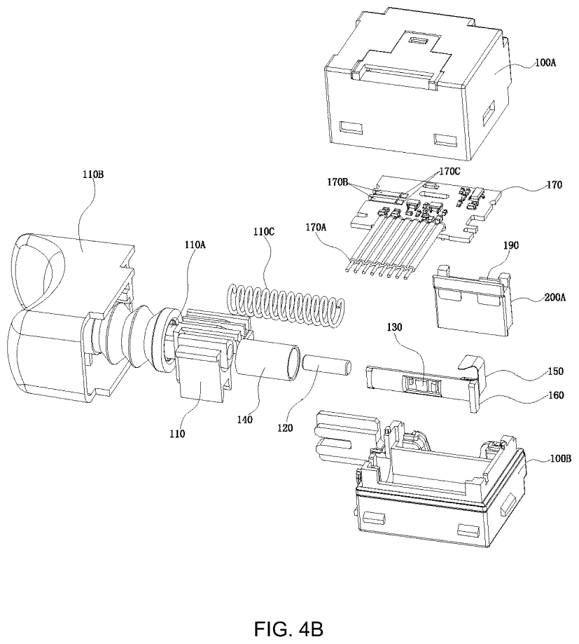

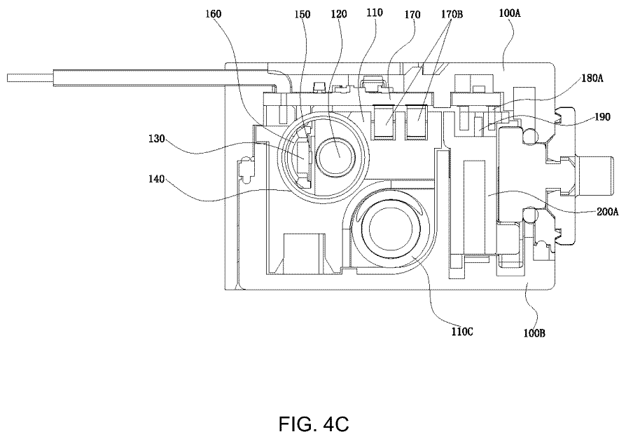

Preferred embodiments of the present application will be described herein with reference to FIG. 4 to FIG. 18. The embodiments include an electrical switch including a non-contact control assembly for use together with an electric tool, such as an electric drill, a grinder, a sanding machine, a saw, and a rotary drive tool. It is to be appreciated and understood that while the present embodiments are described as being used together with the electric tool, this is merely for purposes of illustration of functionality, and the alternative embodiments of the present application may of course be used together with other types of electrical devices, such as an electric gardening tool. Furthermore, while the embodiments of the present application described herein refer to electrical devices that include a motor, it is to be understood that the alternative embodiments of the present application may also be applicable to electrical devices that include a solenoid-type electromechanical unit to achieve operable movement (e.g., reciprocating movement) of the electrical devices.

The electric tool includes a brushless direct-current electric motor, and the brushless direct-current motor, and the brushless direct-current motor includes a rotor and a stator for providing a magnetic field for driving the rotor. The rotor of the brushless direct-current motor includes an output shaft supported by a plurality of bearings for providing an output torque, and is surrounded by permanent magnets that generate a magnetic field. The stator is mounted around the rotor, and an air gap is formed between the stator and the rotor. Stator windings are located in the air gap and are arranged oppositely parallel to an output shaft of the rotor, and can generally be connected in a delta configuration or a three-phase star connection configuration. When a current flows through the stator windings, the current generated in the stator windings generates a magnetic field that is magnetically coupled to the rotor, and the rotor is “dragged” by the magnetic field to rotate. The magnetic field generated by the permanent magnets in a rotor assembly will tend to align itself with the magnetic field generated by the stator such that the rotor will undergo rotational movement. Thus, by controlling the timing and sequential excitations of the stator windings, this enables rotational movement control of a rotor shaft to be set at any desired operation speed and operation direction, as will be described in greater detail below for the non-contact control assembly and the electrical switch including same.

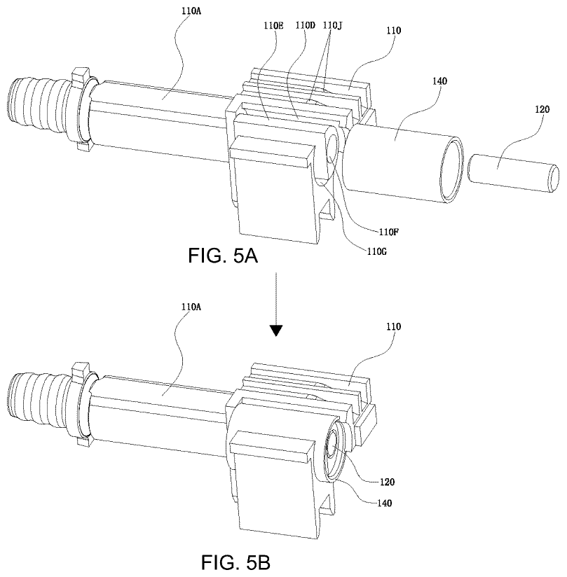

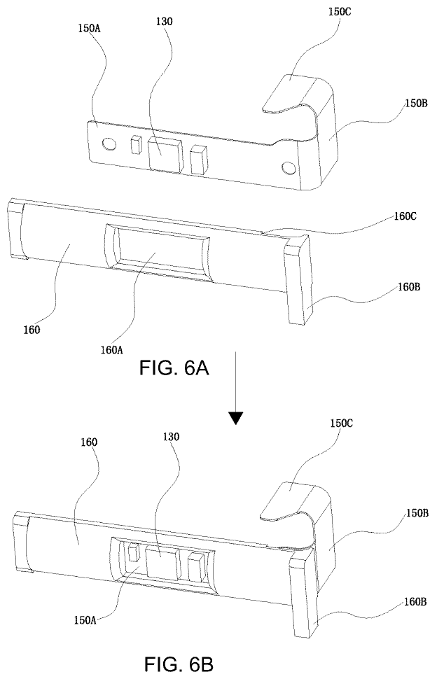

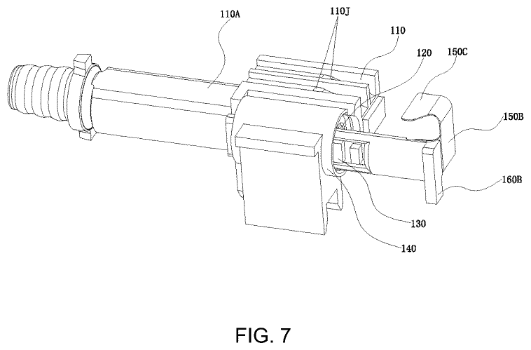

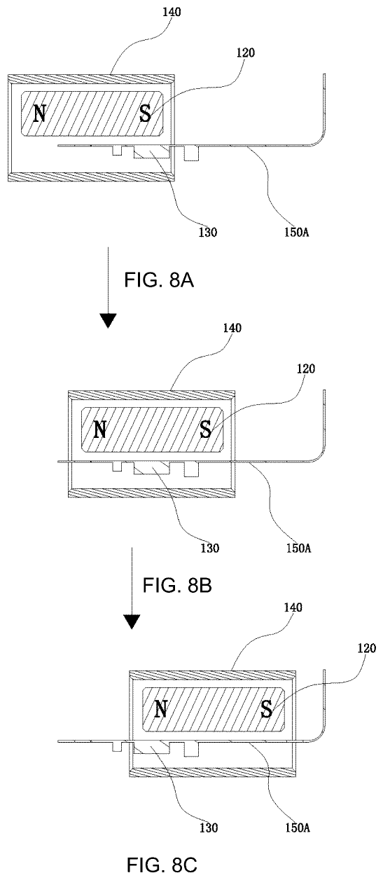

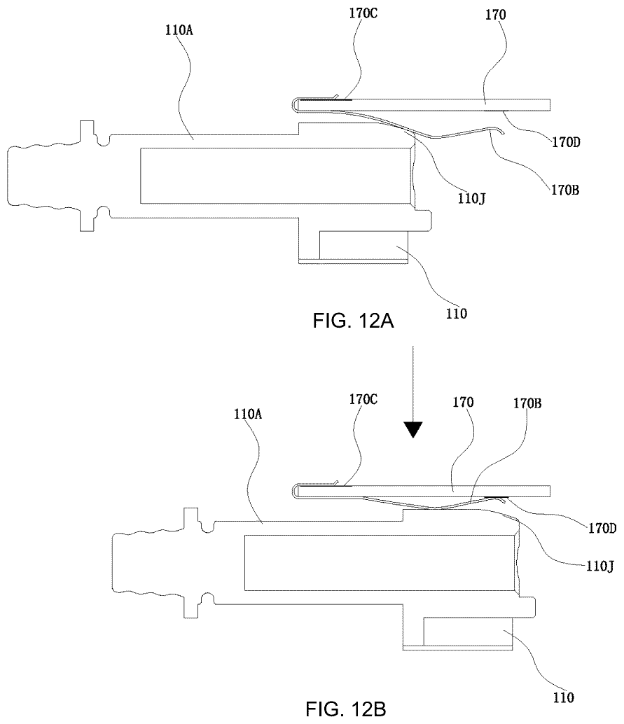

FIG. 4A-FIG. 4C, FIG. 5A-FIG. 5B, FIG. 6A-FIG. 6B, FIG. 7, and FIG. 8A-FIG. 8C show a first embodiment of an electrical switch including a non-contact control assembly according to the present application. As shown in FIG. 4A-FIG. 4C, the non-contact control assembly includes a control assembly housing 100 (molded plastic housing) for being mounted to a main body of an electric tool near a handle of the electric tool. The control assembly housing 100 includes a first housing member 100A and a second housing member 100B that may be in snap connection or threaded connection together to firmly enclose at least some parts and components of the non-contact control assembly therein. In this embodiment, the non-contact control assembly is integrally formed in a contact electrical switch, the contact electrical switch includes at least one pair of electrical switch contacts. The electrical switch contact of this embodiment includes a conductive elastic member 170B, one end of the conductive elastic member 170B is assembled to a main PCB 170 and the conductive elastic member is electrically and mechanically connected by a conductive bonding pad 170C on the main PCB 170, the other end of the conductive elastic member 170B is arranged separately from the main PCB 170, and the other end of the main PCB 170 corresponding to the conductive elastic member 170B is configured with a conductive layer 170D. The non-contact control assembly further includes an actuator 110 operably connected to the electrical switch contacts of the electrical switch, and an actuator shaft 110A having a finger-operable portion. The actuator 110 includes a contact actuation member 110J for closing and opening the electrical switch contacts. In this embodiment, the contact actuation member 110J may be constructed as a sloping surface. When the actuator 110 is in an initial position, the other end of the conductive elastic member 170B is not in contact with the conductive layer 170D on the main PCB 170, the electrical switch contacts are in an open state (as shown in FIG. 12A), and the brushless direct-current motor outputs a zero rotational speed; when the actuator 110 is pushed, the contact actuation member 110J compresses the other end of the conductive elastic member 170B to be in contact with the conductive layer 170D on the main PCB 170, and the electrical switch contacts are in a closed state (as shown in FIG. 12B), thereby achieving an electrical connection between a power supply and the brushless direct-current motor. Specifically, the contact actuation member 110J of the actuator 110 may operate one or more pairs of electrical switch contacts. In this embodiment, the number of the electrical switch contacts is two pairs, and correspondingly, the contact actuation members 110J of the actuators 110 are configured in two groups. Of course, it may be understood that in other embodiments, the number of the electrical switch contacts may also be one or more than two pairs, and the contact actuation member 110J of the actuator 110 is appropriately configured in accordance with the number of the electrical switch contacts. In this embodiment, as shown in FIG. 4B-FIG. 4C, the main PCB 170 may be equipped with two groups of operable conductive elastic members 170B through two groups of conductive bonding pads 170 on the main PCB 170. As shown in FIG. 5A-FIG. 5B, the two groups of contact actuation members 110J of the actuator 110 may operate the corresponding conductive elastic members 170B to be in contact with the corresponding conductive layers 170D on the main PCB 170. The actuator 110 responds to the operation of a finger-operable trigger 110B. When the trigger 110B is compressed down, the actuator shaft 110A linearly slides inwards from an opening in the control assembly housing 100 from position OFF to position ON along a moving axis (X) (thereby closing the electrical switch contacts). Correspondingly, a return spring 100C is clamped between the actuator 110 and an inner side wall of the control assembly housing 100 on one side inwards from the opening in the control assembly housing 100. When a finger of a user releases the trigger 110B, the return spring 100C pushes to promote the actuator 110 to linearly slide outwards from the opening in the control assembly housing 100 from the position ON to the position OFF along the moving axis (X) (thereby opening the electrical switch contacts). By appropriately changing the shape of the conductive elastic member 170B, the shape of the contact actuation member 110J and the position of the conductive elastic member 170B connected to the main PCB 170, the electrical switch contacts may be configured to be normally open and/or normally closed, and the stroke of the corresponding trigger 110B or actuator 110 may also be regulated when the electrical switch contacts are just closed. According to different applications, multiple pairs of electrical switch contacts may perform different logic or functions at positions or position regions corresponding to the actuator 110. The above is an example of the non-contact control assembly used for a contact electrical switch, and it may perform in other structures. In other embodiments, the non-contact control assembly may further be integrally formed in a non-contact electrical switch, the non-contact electrical switch includes at least one contactless switch device, and in response to the movement of the actuator 110 relative to the control assembly housing 100, the contactless switch device is constructed to be closed or opened. The contactless switch device may use at least one of a magnetic amplifier type contactless switch, a vacuum tube type contactless switch, an ionic tube type contactless switch, and a semiconductor contactless switch. Since the contactless switch device does not have a movable contact head component, there are no arcs or sparks during connection and disconnection, the action is quick, the service life is long, reliability is high, and the contactless switch device can form the non-contact electrical switch instead of the electrical switch contacts. The operation mode of the non-contact electrical switch is basically the same as that of the contact electrical switch mentioned above, and only at least one contactless switch device replaces at least one pair of electrical switch contacts of the contact electrical switch, so as to achieve electrical connection or disconnection between the power supply and the brushless direct-current motor.

As shown in FIG. 5A-FIG. 5B, FIG. 6A-FIG. 6B and FIG. 7, a magnetic element 120 is arranged on the actuator 110, and a corresponding magnetic sensor 130 is arranged in the control assembly housing 100, so that when the actuator shaft 110A slides inwards and outwards the control assembly housing 100 along the moving axis (X), the magnetic sensor 130 is configured to sense a changed magnetic field reading from the magnetic element 120, which indicates a relative distance between the magnetic element 120 and the magnetic sensor 130. In this embodiment, the magnetic sensor 130 uses a linear Hall effect sensor, although in other embodiments, any other suitable type of magnetic sensor such as a magnetoresistive effect sensor may be configured as a substitute for sensing the magnetic field or other magnetic related characteristics of the corresponding magnetic element 120. The magnetic element 120 generates a magnetic field in a direction parallel to an axis of a magnetic shielding shell 140, and the direction of the magnetic field is consistent with the direction of movement of the actuator 110. The magnetic element 120 may be any variety of magnets, including but not limited to permanent magnets and electromagnets, thereby providing flexibility in application and functionality. The magnetic element 120 may be in a variety of different shapes, including but not limited to, cylindrical, disk, strip, annular, or cubic shapes. In addition, the magnetic element 120 may also be in customized non-standard shapes, such as elliptical, triangular, or other complex geometrical shapes, to meet specific spatial configuration or functional requirements.

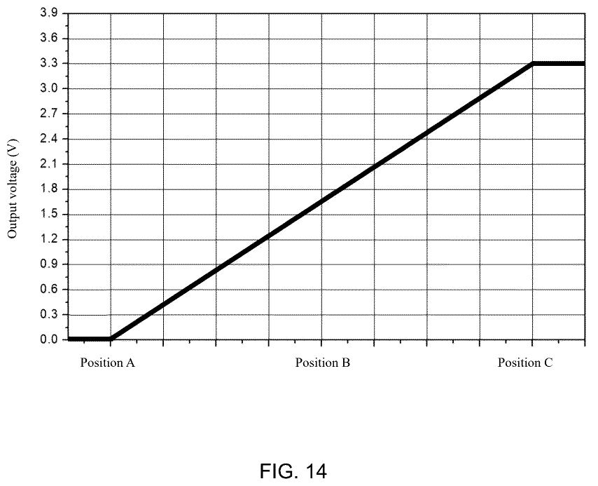

In response to the movement of the actuator 110 relative to the control assembly housing 100, the magnetic sensor 130 and the magnetic element 120 move relative to each other between at least one of a first position and a second position, so that the magnetic sensor 130 senses a first magnetic field reading when at the first position and senses a second magnetic field reading when at the second position. When the actuator 110 is arranged at the position OFF, the electrical switch contacts in the electrical switch are opened and the brushless direct-current motor outputs zero rotational speed. When the actuator shaft 110A moves to the position ON, the electrical switch contacts in the electrical switch are closed, and electrical communication is achieved between the power supply and the motor. When the electrical switch contacts are closed, the magnetic element 120 may be arranged at any of a plurality of possible positions relative to the magnetic sensor 130, and this depends on the strength with which the finger of the user presses the trigger 110B. The magnetic sensor 130 is configured to output variable voltage, variable resistance or digital output directly proportional to the magnetic field sensed by the magnetic sensor 130, to indicate the sensed magnetic field readings mentioned above. Taking the output of a variable voltage as an example, the output voltage of the magnetic sensor 130 is not only proportional to an input voltage, but also can linearly change according to a change in magnetic flux density perpendicular to a marking surface. The magnetic sensor 130 can detect the magnetic flux density perpendicular to its designated active surface and make a response to same. The change in the output voltage is directly related to the magnitude of the magnetic flux in sensing direction of the magnetic sensor and the polarity (magnetic flux direction) in the sensing direction of the magnetic sensor, thereby establishing a proportional relationship between the input voltage and the output voltage. Specifically, when the magnetic sensor 130 is located at an S pole and has a high magnetic field intensity (the magnetic flux in the sensing direction of the magnetic sensor is greater than a saturation value), the output voltage of the magnetic sensor 130 is zero volt, as shown in FIG. 8A. As the magnetic sensor 130 gradually moves from the S pole to a zero perpendicular magnetic flux area at a center of the magnetic element 120, the output voltage of the magnetic sensor 130 gradually increases to half of the input voltage, as shown in FIG. 8B. As the magnetic sensor 130 continues to move towards an N pole, the output voltage of the magnetic sensor 130 will increase further, and when the magnetic sensor reaches the N pole having a high magnetic field intensity (the magnetic flux in the sensing direction of the magnetic sensor is greater than the saturation value), the output voltage will reach equal to the input voltage, as shown in FIG. 8C. This function enables the magnetic sensor 130 to accurately indicate the measured first magnetic field reading and second magnetic field reading, thereby providing reliable data for the control module for further processing. In the magnetic sensor 130 working at a set input voltage of 3.3 V, the output state changes significantly according to the proximity and polarity of the magnetic field. A voltage change curve in an ideal state of the magnetic sensor 130 when moving to different positions is shown in FIG. 14, prior to position A to position A, the output voltage of the magnetic sensor 130 is zero volt; at position B, the output voltage of the magnetic sensor 130 is 1.65 V, which is half of the input voltage; and finally, at position C to post position C, the output voltage of the magnetic sensor 130 is 3.3 V, which is equal to the input voltage. Depending on working voltages of circuits and devices, the input voltage of the magnetic sensor 130 may be other voltages, such as 5.0 V.

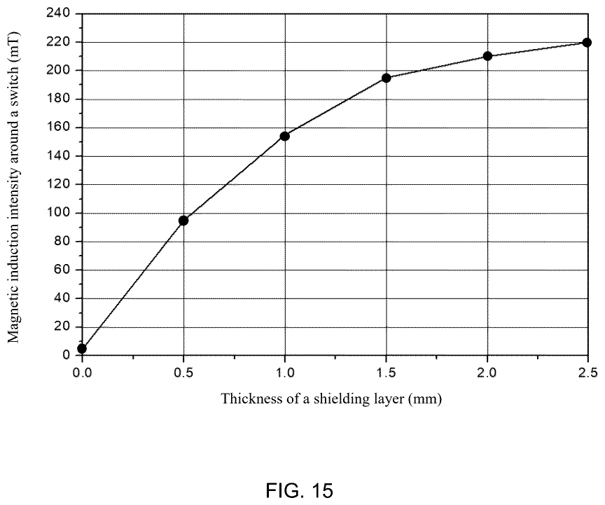

The magnetic shielding shell 140 is operably connected to the actuator 110, and the magnetic element 120 is mounted to the actuator 110 and located in the magnetic shielding shell 140, wherein the magnetic shielding shell 140 includes a three-dimensional closed loop structure having two open surfaces, in response to the movement of the actuator 110 relative to the control assembly housing 100, the magnetic sensor 130 is able to enter an interior of the magnetic shielding shell 140 through one of the open surfaces of the magnetic shielding shell 140 and move towards the other of the open surfaces of the magnetic shielding shell 140 relative to the magnetic element 120 in the interior of the magnetic shielding shell 140, so as to effectively eliminate interference of an external magnetic signal source of the non-contact control assembly with sensing by the magnetic sensor 130 on the first magnetic field reading and the second magnetic field reading produced by the magnetic element 120 in response to the movement of the actuator 110. The design of the magnetic shielding shell 140 has diversity, and common shapes include cylindrical, square or rectangular, and annular shapes, and special non-standard shapes such as trapezoidal, elliptical, or other complex geometrical shapes. The magnetic shielding shell 140 is made of a magnetic material selected due to its high magnetic permeability and low magnetic saturation characteristics, so that an optimal shielding effect can be ensured. Materials suitable for manufacturing include silicon steel, low-carbon steel, permalloy, and supermalloy which can attenuate magnetic interference. Dimensionally, the length of the magnetic shielding shell 140 is sufficient to encase the magnetic element 120 and the magnetic sensor 130, thereby providing overall magnetic shielding. For example, the magnetic shielding shell 140 may include a hollow cylindrical structure as shown in the examples of FIG. 5A-FIG. 5B. In addition, both the magnetic element 120 and the magnetic shielding shell 140 are configured to be positioned on the actuator 110, the magnetic element 120 is located on one side of the magnetic shielding shell 140, and the magnetic sensor 130 located on the opposite side of the magnetic element 120 can enter the magnetic shielding shell 140 through the open surface on the other side of the magnetic shielding shell 140 and move towards the other open surface of the magnetic shielding shell 140 relative to the magnetic element 120 in the magnetic shielding shell 140, to reduce the occurrence of external magnetic signal source interference. The magnetic element 120 and the magnetic shielding shell 140 can be mounted into the actuator 110 using a variety of connection methods, such as snap-fit, hot riveting, insert molding, an adhesive, interlocking function, riveting, and screwing, to ensure that the magnetic element 120 and the magnetic shielding shell 140 are firmly mounted on the actuator 110, so as to improve the overall stability and efficiency of the non-contact control assembly. Not only is a secure connection of the components during the movement ensured, but also the flexibility of selecting the most suitable mounting method according to the requirements of different applications is provided. In this embodiment, the actuator 110 is provided with a mounting groove 110D matching the magnetic shielding shell 140, the magnetic shielding shell 140 is embedded in the mounting groove 110D, a fixed block 110E is configured on an inner side of the actuator 110 corresponding to the magnetic shielding shell 140, one end of the fixed block 110E is transversely provided with an accommodating groove 110F matching the magnetic element 120, the magnetic element 120 is embedded in the accommodating groove 110F, the fixed block 110E is in a semi-cylindrical shape, an accommodating hole 110G for the magnetic sensor 130 to pass through is formed between the fixed block 110E and an inner side wall of the magnetic shielding shell 140, and the accommodating hole 110G is in a semi-cylindrical shape. The arrangement of the described structures ensures that the magnetic element 120 and the magnetic shielding shell 140 are firmly mounted in the actuator 110, thereby improving the overall stability and efficiency of the non-contact control assembly. The effectiveness of the magnetic shielding shell 140 is greatly influenced by its thickness, and the thicker magnetic shielding shell 140 generally provides better protection against external magnetic interference. However, there is no need to increase the thickness indefinitely, and a thickness, beyond a certain thickness, about 0.5 mm or more, for example, 0.5-2.5 mm, specifically 0.5 mm, 1 mm, 1.5 mm, 2 mm or 2.5 mm, etc., may be selected to achieve a good shielding effect. As shown in FIG. 15, the voltage change threshold of the magnetic sensor 130 is set to a maximum acceptable value beyond which the change will be considered a fault. By adjusting a surrounding magnetic field, it is tested which magnetic shielding designs of different thicknesses are more effective. Specifically, the applicant will use an external magnetic field in mT to test magnetic shielding shells 140 of various thicknesses. According to experiments, the change in voltage output by the magnetic sensor 130 still keeps below a maximum acceptable output change value when the external magnetic field intensity is lower than the magnetic induction intensity corresponding to the curve. In certain embodiments, the magnetic shielding shell 140 may function as magnetic shielding and waterproof sealing simultaneously to provide dual functions, which may avoid the need to use separate magnetic shielding and waterproof elements in the device. For example, after the magnetic shielding shell 140 is mounted, coating or potting is performed on exposed surfaces of the magnetic element 120 and the magnetic sensor 130. This arrangement may simplify the overall design, save manufacturing time and costs, and reduce complexity.

As shown in FIG. 6A-FIG. 6B, the non-contact control assembly further includes a connection member 150, and the connection member 150 is constructed for establishing a telecommunication connection (a power and signal connection) between the magnetic sensor 130 and the control module, to transmit variable speed control signals. In this embodiment, the connection member 150 may function as a connection medium for mounting the magnetic sensor 130 on the surface, facilitating integrating same into a main PCB 170. The connection member 150 is designed specifically for assembly and electrical interconnection of the magnetic sensor 130, to ensure seamless integration with the function of the magnetic sensor 130. In other embodiments, a group of electric wires, metal bars, or any other conductive materials may be used in place of the connection member 150. In this embodiment, the connection member 150 includes a sensor PCB 150A, the magnetic sensor 130 is mounted to the sensor PCB 150A, and the non-contact control assembly includes a main PCB 170 that is operably connected to the sensor PCB 150A. Further, the sensor PCB 150A is a flexible PCB, one end of the flexible PCB is connected to one end of the main PCB 170, the other end of the flexible PCB is separated from the other end of the main PCB 170 to form a gap, the gap is constructed for a sidewall of the magnetic shielding shell 140 to move via the gap, such that the magnetic sensor 130 enters the interior of the magnetic shielding shell 140 along with the flexible PCB through one of the open surfaces of the magnetic shielding shell 140 and moves towards the other of the open surfaces of the magnetic shielding shell 140 relative to the magnetic element 120 in the interior of the magnetic shielding shell 140. Specifically, the flexible PCB is in a long strip shape, a right end of the flexible PCB is bent backwards to form a first bent portion 150B, and a top of the first bent portion 150B is bent upwards to form a second bent portion 150C, so that the flexible PCB is electrically and mechanically connected to the main PCB 170 through the second bent portion 150C.

In order to make the flexible PCB smoothly move inside the magnetic shielding shell 140 relative to the magnetic element 120, the non-contact control assembly further includes a support member 160 for supporting the flexible PCB, the support member 160 is mounted inside the control assembly housing 100, and at least a portion of the support member 160 is connected to the other end of the flexible PCB. Specifically, the support member 160 is in a long strip shape, a position of the middle of the support member 160 corresponding to the magnetic sensor 130 is provided with an accommodating hole 160A, and the magnetic sensor 130 is exposed from the accommodating hole 160A. In other embodiments, when the magnetic sensor 130 is relatively thin in thickness, the accommodating hole 160A may be replaced with an accommodating groove. A right end of the support member 160 is bent downwards to form a snap-connection portion 160B so as to be mounted in a snap-connection manner in the control assembly housing 100 through the snap-connection portion 160B. In addition, a rear end of the support member 160 is transversely provided with a fixing groove 160C matching the flexible PCB, and the flexible PCB is embedded in the fixing groove 160C. The arrangement of the described structures facilitates the mounting and fixation of the flexible PCB. The magnetic sensor 130 is configured for surface mounting and fixed on the flexible PCB, and the flexible PCB is then firmly connected to the firm support member 160, to ensure accurate positioning of the magnetic sensor 130 in the non-contact control assembly. The flexible PCB can be firmly connected to the firm support member 160 by, for example, hot stacking, an adhesive, interlocking feature, riveting, or a screw, to ensure that the flexible PCB remains at a secure and accurate position in the non-contact control assembly, thereby ensuring consistent performance and reliability of the magnetic sensor 130 in its intended application. The magnetic element 120 and the magnetic shielding shell 140 are mounted together on the actuator 110, and throughout the movement of the actuator 110, the magnetic element 120 remains at a constant position relative to the magnetic shielding shell 140, so that the magnetic element 120 can always shield magnetic interference. Meanwhile, the magnetic sensor 130 is arranged at a specific distance from the magnetic element 120, so as to perform accurate detection, and is firmly fixed in the control assembly housing 100. Throughout the movement, the magnetic shielding shell 140 can effectively protect the magnetic sensor 130, to ensure that the magnetic sensor is not affected by any external magnetic interference, thereby keeping the accuracy of the reading of the magnetic sensor 130 and the function of the actuator 110.

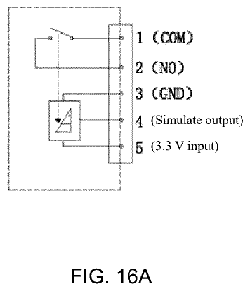

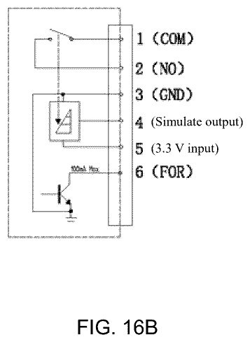

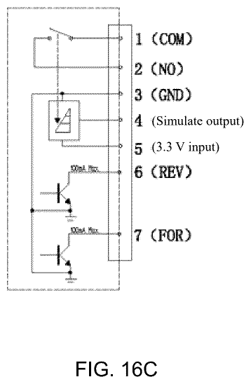

A connection port 170A is used for establishing a power and signal connection with a motor control module, the control module is operably connected to the magnetic sensor 130 and configured for controlling, by referring to output of the magnetic sensor 130 indicating a sensed first magnetic field reading and a sensed second magnetic field reading, respectively, the electrical device to operate at at least one of a first speed or torque and a second speed or torque. By means of the electrical connection with the control module, in addition to determining, by means of non-contact magnetic sensing output, electrical device output and waking up a power supply of a system provided by the electrical switch, whether a motor can be allowed to start when being turned off can be determined by means of an on or off state of the electrical switch contacts or the contactless switch device. When the external magnetic field exceeds the designed level of immunity, this may provide multiple motor false triggering protection. The electrical switch including the non-contact control assembly shown in this embodiment is a signal switch, can establish a power and signal connection with the motor control module through the connection port 170A (including power input and signal output). In this embodiment, the connection port 170A establishes a power and signal connection with the motor control module through connection wires. Of course, the connection port 170A can also establish a power and signal connection with the motor control module through connectors or the like. In other embodiments, the signal switch of the present application and the motor control module may be integrated into one, to construct an integrated switch, and the two share one PCB. The motor control module includes a motor control circuit that receives a variable voltage signal and outputs an electrical control module signal as a response. Signals of the motor control module drive operation of a power module, and the power module includes a plurality of MOSFETs connected to corresponding input terminals of the stator windings of the brushless direct-current motor. By referring to sequentially starting, by the control module, each stator winding through the MOSFETs according to a controlled timing sequence, the permanent magnets of the rotor continuously follow an advancing magnetic field generated by the stator windings. The control module includes a microcontroller semiconductor that is configured to output control module signals. The signals drive the multiple MOSFETs of the power module to energize their corresponding stator windings at a predetermined timing sequence, thereby causing the brushless direct-current motor to operate in a predetermined manner (i.e., speed, direction, torque) corresponding to the movement of the actuator 110 indicated by the output of the magnetic sensor 130. The speed and torque of the brushless direct-current motor depend on the amount of power that can be provided to the stator windings through its corresponding input MOSFETs. In these embodiments, the amount of power provided to the stator windings can be controllably changed by using pulse width modulation techniques, whereby the output of a timing signal generator (such as a “555” circuit) is used as an input of an MOSFET gate to appropriately achieve high-speed switching of the MOSFETs, and the resulting power is switched to the stator windings through the MOSFETs, thereby providing the amount of required speed and torque generated by the brushless direct-current motor. Therefore, timing signal generator signals can be used as control module signals for controlling the operation of the MOSFETs. In certain embodiments, the control module may further include a voltage regulation and protection circuit to regulate an input voltage from the direct-current power supply to each MOSFET. The sensor PCB 150A is operably connected to a control module PCB provided with a control module semiconductor through the main PCB 170, and the main PCB 170 and the control module PCB can be soldered together or integrated into one. The control module semiconductor and other electronic parts and components arranged on the control module PCB are powered by the power supply of the electrical device, and in this embodiment, a battery module may also be included. As shown in FIG. 16A, the magnetic sensor 130 simulates an output signal, and is powered by an external 3.3 V DC power supply, and simulating the output signal is controlled by the magnetic element 120 and generates a signal output voltage. Depending on working voltages of circuits and devices, the input voltage of the magnetic sensor 130 may be other voltages, such as 5.0 V.

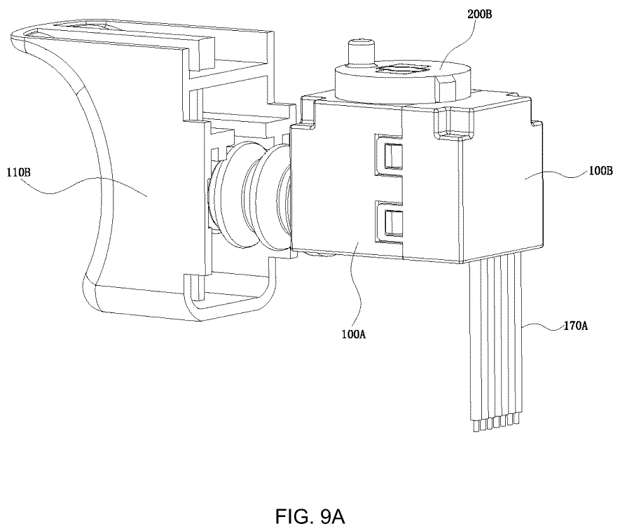

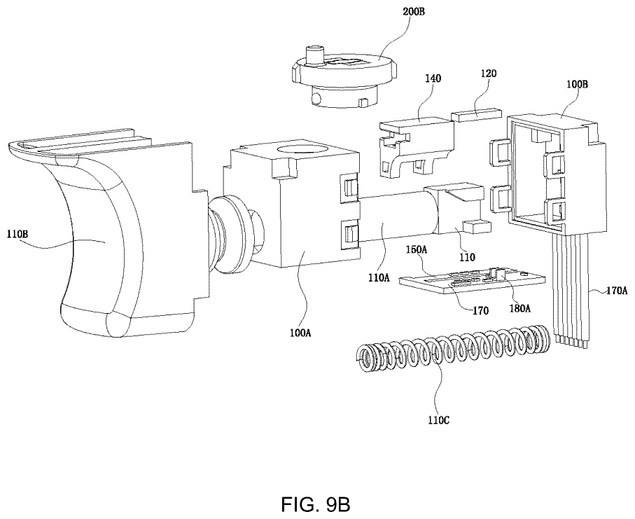

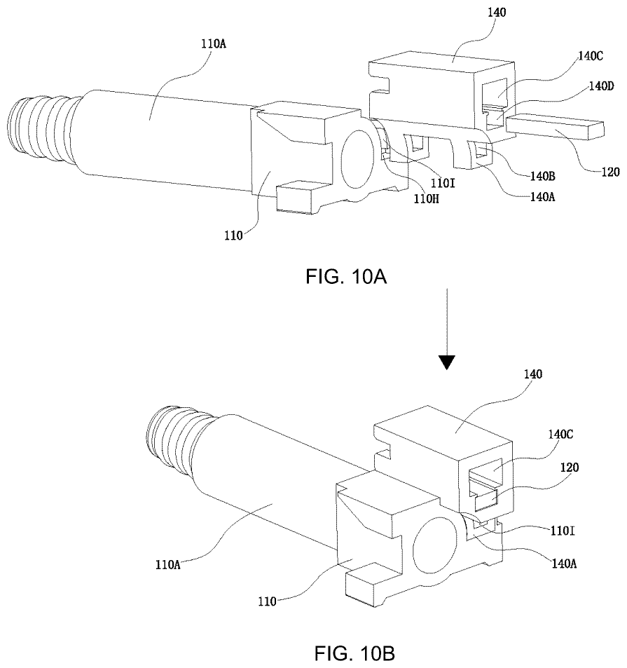

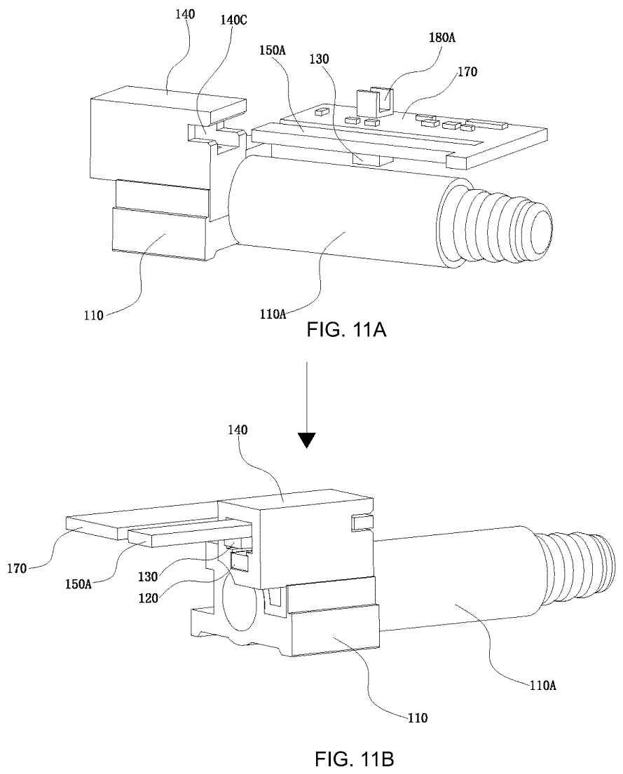

FIG. 9A-FIG. 9B, FIG. 10A-FIG. 10B, and FIG. 11A-FIG. 11B show a second embodiment of an electrical switch including a non-contact control assembly according to the present application. In this embodiment, the sensor PCB 150A is a rigid PCB, one end of the rigid PCB is connected to one end of the main PCB 170, the other end of the rigid PCB is separated from the other end of the main PCB 170 to form a gap, the gap is constructed for a sidewall of the magnetic shielding shell 140 to move via the gap, such that the magnetic sensor 130 enters the interior of the magnetic shielding shell 140 along with the rigid PCB through one of the open surfaces of the magnetic shielding shell 140 and moves towards the other of the open surfaces of the magnetic shielding shell 140 relative to the magnetic element 120 in the interior of the magnetic shielding shell 140. In this embodiment, one end of the rigid PCB is connected to one end of the main PCB 170 as a whole. It may be understood that in other embodiments, one end of the rigid PCB and one end of the main PCB 170 may also be connected in manners such as soldering. The control assembly housing 100 of this embodiment has an extremely compact size and can be assembled in a front-back direction or an up-down direction. The magnetic shielding shell 140 shown in FIG. 10A-FIG. 10B exhibits a hollow cubic shape, a plurality of protrusions 140A are configured at a bottom thereof, and these protrusions 140A facilitate the connection of the magnetic shielding shell 140 into the actuator 110. Specifically, positions of the actuator 110 corresponding to the protrusions 140A are provided with grooves 110H, the plurality of protrusions 140A are all embedded in the grooves 110H, each protrusion 140A is provided with a clamping hole 140B, and clamping blocks 1101 connected to the corresponding clamping holes 140B in a clamped manner are configured in the grooves 110H. The magnetic shielding shell 140 is provided with a through hole 140C that penetrates through both sides thereof, and the design of the through hole 140C allows the rigid PCB provided with the magnetic sensor 130 to be inserted. One end of the magnetic shielding shell 140 is further provided with a mounting groove 140D for mounting the magnetic element 120, and the magnetic element 120 is embedded in the mounting groove 140D. In other embodiments, a top of the mounting groove 140D may be in communication with a bottom of the through hole 140C, so that the magnetic sensor 130 can better sense a magnetic field reading at the position where it is. The magnetic element 120 of this embodiment can use different shapes, indicating that the shapes of the magnetic shielding shell 140 and the magnetic element 120 may change, but the operation principles thereof remain unchanged.

FIG. 4B-FIG. 4C and FIG. 16B show a third embodiment of an electrical switch including a non-contact control assembly according to the present application. In this embodiment, the non-contact control assembly further includes a non-contact commutation mechanism for controlling a direction of operation of a motor, i.e., a forward or reverse operation mode. The non-contact commutation mechanism includes an optical sensor, a shielding element 190, and a commutation member, and the optical sensor is mounted into the control assembly housing 100 and the shielding element 190 is mounted to the commutation member. As shown in FIG. 16B, the optical sensor is connected to an open drain circuit having an external pull-up resistor for outputting a signal. In this embodiment, as shown in FIG. 4B-FIG. 4C, the optical sensor includes a first optical sensor 180A, the first optical sensor 180A is mounted on the main PCB 170, and output of the first optical sensor 180A is connected to a “forward rotation” input pin of a control module semiconductor chip. Therefore, the control module is constructed to change the rotation direction of the motor by reversing the voltage on the stator windings-in fact, reversing a communication sequence, so that the motor changes the direction to rotate according to its forward or reverse rotation input pin activated by the optical sensor output during operation. In this embodiment, the commutation member includes a sliding member 200A, the shielding element 190 is fixed to a top of the sliding member 200A, the sliding member 200A can move linearly along the control assembly housing 100, such as moving left and right along the control assembly housing 100, and when the sliding member 200A moves to a rightward position, the shielding element 190 is constructed for shielding a gap of the first optical sensor, so that the “forward rotation” input pin will be activated. On the contrary, when the sliding member 200A moves to a leftward position, the shielding element 190 is constructed for not shielding the gap of the first optical sensor, so that the “forward rotation” input pin of the control module semiconductor chip will not be activated. In other embodiments, as shown in FIG. 9A-FIG. 9B, the commutation member includes a rotating part 200B, the rotating part 200B can pivot around a pivot member, the shielding element 190 fixed to a bottom of the rotating part 200B, and the first optical sensor 180A is arranged on a circumference of the main PCB 170 centered on the pivot member. When the rotating part 200B rotates to a rightward position, the shielding element 190 is constructed for shielding the gap of the first optical sensor, so that the “forward rotation” input pin will be activated. On the contrary, when the rotating part 200B rotates to a leftward position, the shielding element 190 is constructed for not shielding the gap of the first optical sensor, so that the “forward rotation” input pin of the control module semiconductor chip will not be activated.

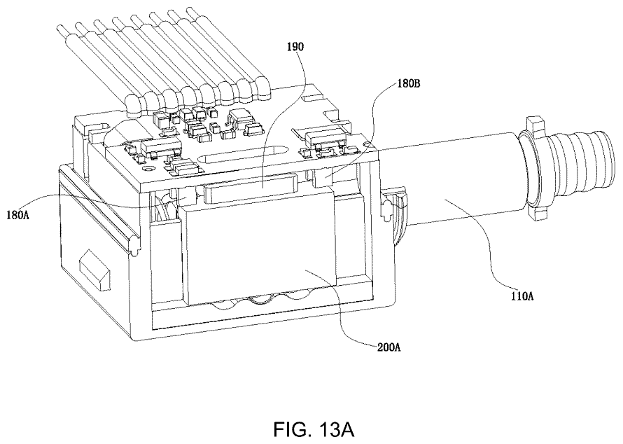

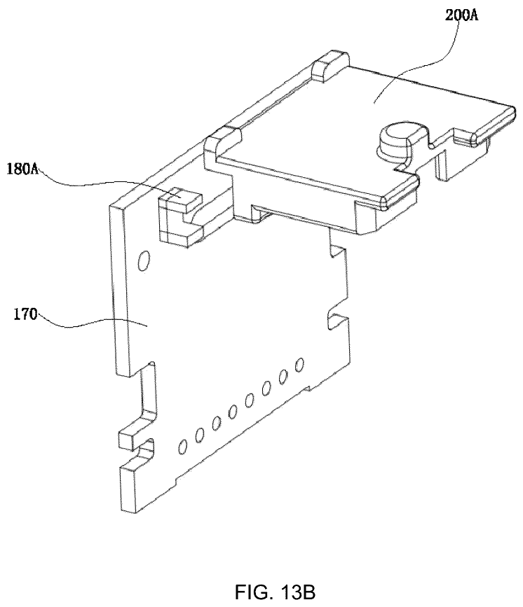

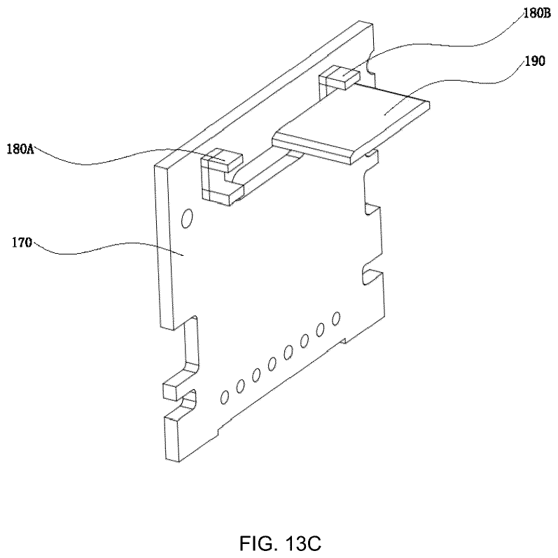

FIG. 13A-FIG. 13C and FIG. 16C show a fourth embodiment of an electrical switch including a non-contact control assembly according to the present application. In this embodiment, an optical sensor includes a first optical sensor 180A and a second optical sensor 180B, as shown in FIG. 16C, the optical sensor is connected to an open drain circuit having an external pull-up resistor for outputting a signal. Output of the first optical sensor 180A is connected to a “forward rotation” input pin of a control module semiconductor chip, and output of the second optical sensor 180B is connected to a “reverse rotation” input pin of a control module semiconductor chip. Therefore, the control module is constructed to change the rotation direction of the motor by reversing the voltage on the stator windings-in fact, reversing a communication sequence, so that the motor changes the direction to rotate according to its forward or reverse rotation input pin activated by the optical sensor output during operation. As shown in FIG. 13B-FIG. 13C, the first optical sensor 180A and the second optical sensor 180B are mounted on the main PCB 170. In this embodiment, the commutation member includes a sliding member 200A, the shielding element 190 is fixed to a top of the sliding member 200A, the sliding member 200A can move linearly along the control assembly housing 100, such as moving left and right along the control assembly housing 100, and when the sliding member 200A moves to a rightward position, the shielding element 190 is constructed for shielding a gap of the first optical sensor 180A, so that the “forward rotation” input pin will be activated. On the contrary, when the sliding member 200A moves to a leftward position, the shielding element 190 is constructed for shielding a gap of the second optical sensor 180B, but not shielding the gap of the first optical sensor 180A, so that the “forward rotation” input pin of the control module semiconductor chip will not be activated, and the “reverse rotation” input pin will be activated. In other embodiments, the commutation member includes a rotating part, the rotating part can pivot around a pivot member, the shielding element 190 fixed to a bottom of the rotating part, and the first optical sensor 180A and the second optical sensor 180B are arranged on a circumference of the main PCB 170 centered on the pivot member. When the rotating part rotates to a rightward position, the shielding element 190 is constructed for shielding the gap of the first optical sensor, so that the “forward rotation” input pin will be activated. On the contrary, when the rotating part rotates to a leftward position, the shielding element 190 is constructed for shielding a gap of the second optical sensor 180B, but not shielding the gap of the first optical sensor 180A, so that the “forward rotation” input pin of the control module semiconductor chip will not be activated, and the “reverse rotation” input pin will be activated.

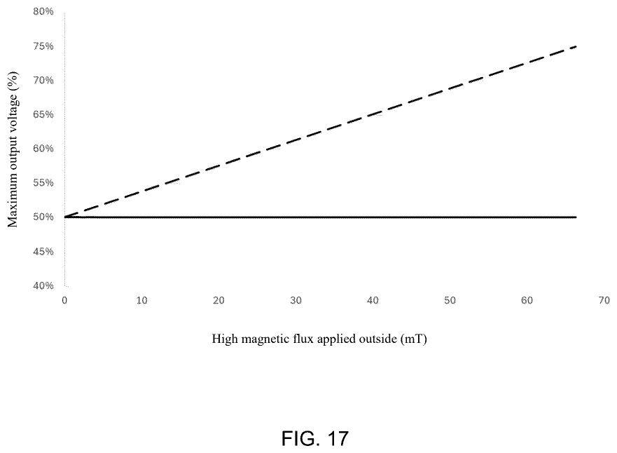

To verify the anti-external magnetic interference capability of the electrical switch according to the present application, the applicant conducted a series of tests. These tests include applying magnetic flux of different intensities from zero to approximately 70 milliTesla to the electrical switch. The applicant first conducted a test without a magnetic shielding shell 140. A result is shown by a dashed line in FIG. 17, and it is observed that a switch output voltage increases from 50% of a maximum output voltage to approximately 75% of the maximum output voltage. Then, the applicant conducted a test with a magnetic shielding shell 140. A result is shown by a solid line in FIG. 17. Even under the magnetic interference of 70 milliTesla, the output voltage of the switch can stably remain at 50% of the maximum output voltage, indicating that the external magnetic flux has not caused any changes or errors in the output voltage. This confirms that the electrical switch of the present application can effectively resist external magnetic interference, which is extremely beneficial for maintaining the stability of operation of the electric tools.

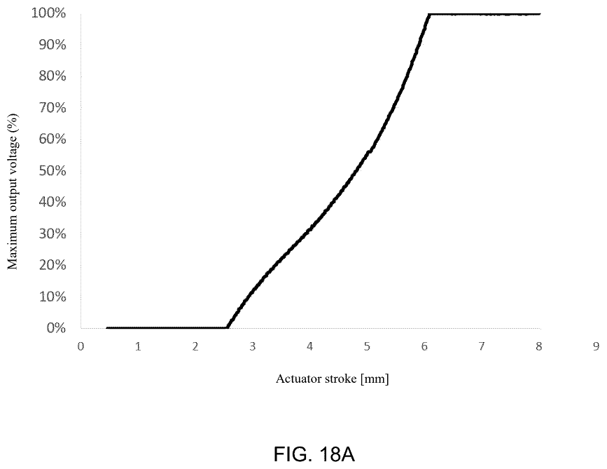

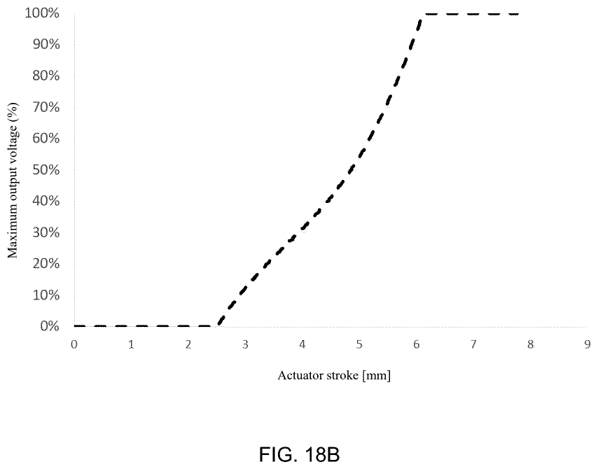

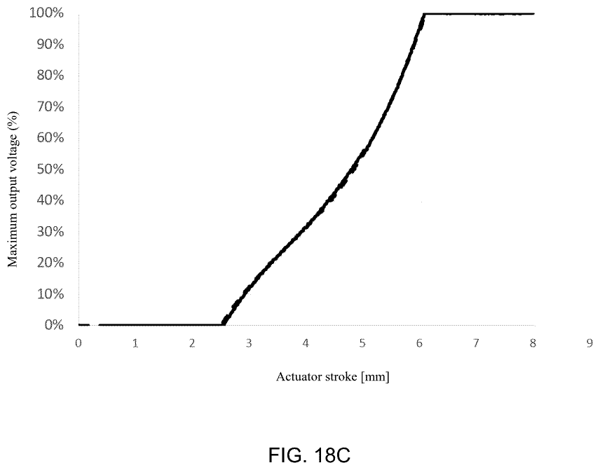

In addition, a baseline test conducted first by the applicant shows (an output voltage display form in FIG. 18A-FIG. 18C is displayed in a maximum output voltage percentage) that without external magnetic interference, the output voltage of the magnetic sensor 130 changes almost linearly, as shown in FIG. 18A, gradually increasing from approximately 0 volt to the maximum value of the input voltage. Next, we conducted an external magnetic interference test on the electrical switch, using a magnet having a high magnetic flux (approximately 210 milliTesla) as an interference source. A test result is shown in FIG. 18B. A combination result is shown in FIG. 18C, where a solid line represents an output voltage without external magnetic interference, and a dashed line represents an output voltage with external magnetic interference. The results show that even under external magnetic interference, the output voltage almost overlaps with the state without external magnetic interference, further proving that the effect of the electrical switch of the present application in resisting external magnetic interference is significant.

The positive is that the embodiments of the present application contribute to providing advantages over the prior arts, wherein by using a special magnetic shielding shell 140, compared with the prior arts 1-4, magnetic interference with signal transmission between the magnetic element 120 and the magnetic sensor 130 can be effectively eliminated, thereby improving the reliability and stability of device operation, and preventing device misoperation caused by sensing false signal transmission due to external magnetic interference. Secondly, the magnetic shielding shell 140 can be directly mounted in the control assembly housing 100, and compared with the design of placing same outside the housing in the prior art 1, less magnetic shielding material and volume are used, thereby reducing costs. Furthermore, the magnetic shielding shell 140 uses the design of both ends open, which relatively simplifies the manufacturing process of the magnetic shielding shell 140 compared with the structure with one end closed in the prior art 4, so that the manufacturing cost is lower. In addition, compared with the prior art 4, the embodiments of the present application further have the advantages of reducing the size of the control assembly and reducing the volume and cost of the magnetic element.

Those skilled in the art will understand that the present application described herein is susceptible to changes and modifications other than those specifically described without departing from the scope of the present application. All such changes and modifications which become apparent to those skilled in the art shall be considered as falling within the spirit and scope of the present application as broadly described above. It is to be understood that the present application includes all such changes and modifications. The present application further includes all steps and features referred to or indicated in the specification, individually or collectively, and any and all combinations of any two or more of the steps or features.

Reference to any prior art in this specification is not, and shall not be taken as, an acknowledgement or any form of suggestion that the prior art forms part of the common general knowledge.

1. A non-contact control assembly for controlling operation of an electrical device, comprising:
a control assembly housing;
a magnetic sensor;
a magnetic element;
an actuator, configured to move relative to the control assembly housing, wherein in response to movement of the actuator relative to the control assembly housing, the magnetic sensor and the magnetic element move relative to each other between at least one of a first position and a second position, so that the magnetic sensor senses a first magnetic field reading when at the first position and senses a second magnetic field reading when at the second position;
a connection port, for establishing a power and signal connection with a motor control module, wherein the motor control module is operably connected to the magnetic sensor and configured for controlling, by referring to output of the magnetic sensor indicating a sensed first magnetic field reading and a sensed second magnetic field reading, respectively, the electrical device to operate at at least one of a first speed or torque and a second speed or torque; and
a magnetic shielding shell, operably connected to the actuator, and the magnetic element being mounted to the actuator and located in the magnetic shielding shell, wherein the magnetic shielding shell comprises a three-dimensional closed loop structure having two open surfaces, in response to the movement of the actuator relative to the control assembly housing, the magnetic sensor is able to enter an interior of the magnetic shielding shell through one of the open surfaces of the magnetic shielding shell and move towards the other of the open surfaces of the magnetic shielding shell relative to the magnetic element in the interior of the magnetic shielding shell, so as to effectively eliminate interference of an external magnetic signal source of the non-contact control assembly with sensing by the magnetic sensor on the first magnetic field reading and the second magnetic field reading produced by the magnetic element in response to the movement of the actuator.

2. The non-contact control assembly for controlling operation of an electrical device according to claim 1, wherein the magnetic sensor comprises a linear Hall effect sensor or a magnetoresistive effect sensor.

3. The non-contact control assembly for controlling operation of an electrical device according to claim 1, wherein the non-contact control assembly further comprises a connection member, and the connection member is constructed for establishing a telecommunication connection between the magnetic sensor and the motor control module.

4. The non-contact control assembly for controlling operation of an electrical device according to claim 3, wherein the connection member comprises a sensor PCB, the magnetic sensor is mounted to the sensor PCB, and the non-contact control assembly further comprises a main PCB that is operably connected to the sensor PCB.

5. The non-contact control assembly for controlling operation of an electrical device according to claim 4, wherein the sensor PCB is a flexible PCB, one end of the flexible PCB is connected to one end of the main PCB, the other end of the flexible PCB is separated from the other end of the main PCB to form a gap, the gap is constructed for a sidewall of the magnetic shielding shell to move via the gap, such that the magnetic sensor enters the interior of the magnetic shielding shell along with the flexible PCB through one of the open surfaces of the magnetic shielding shell and moves towards the other of the open surfaces of the magnetic shielding shell relative to the magnetic element in the interior of the magnetic shielding shell.

6. The non-contact control assembly for controlling operation of an electrical device according to claim 5, wherein the non-contact control assembly further comprises a support member for supporting the flexible PCB, the support member is mounted inside the control assembly housing, and at least a portion of the support member is connected to the other end of the flexible PCB.

7. The non-contact control assembly for controlling operation of an electrical device according to claim 4, wherein the sensor PCB is a rigid PCB, one end of the rigid PCB is connected to one end of the main PCB, the other end of the rigid PCB is separated from the other end of the main PCB to form a gap, the gap is constructed for a sidewall of the magnetic shielding shell to move via the gap, such that the magnetic sensor enters the interior of the magnetic shielding shell along with the rigid PCB through one of the open surfaces of the magnetic shielding shell and moves towards the other of the open surfaces of the magnetic shielding shell relative to the magnetic element in the interior of the magnetic shielding shell.

8. The non-contact control assembly for controlling operation of an electrical device according to claim 7, wherein one end of the rigid PCB is connected to one end of the main PCB as a whole.

9. The non-contact control assembly for controlling operation of an electrical device according to claim 1, wherein the non-contact control assembly is integrally formed in a contact electrical switch, the contact electrical switch comprises at least one pair of electrical switch contacts, and the actuator comprises a contact actuation member for closing or opening the electrical switch contacts.

10. The non-contact control assembly for controlling operation of an electrical device according to claim 1, wherein the non-contact control assembly is integrally formed in a non-contact electrical switch, the non-contact electrical switch comprises at least one contactless switching device, and in response to the movement of the actuator relative to the control assembly housing, the contactless switching device is constructed to be closed or opened.

11. The non-contact control assembly for controlling operation of an electrical device according to claim 1, wherein the output of the magnetic sensor comprises variable voltage, variable resistance or digital output, to indicate at least one of the sensed first magnetic field reading and the sensed second magnetic field reading.

12. The non-contact control assembly for controlling operation of an electrical device according to claim 1, wherein an operation speed or torque of the electrical device comprises an operation speed or torque of a motor of the electrical device.

13. The non-contact control assembly for controlling operation of an electrical device according to claim 1, further comprising:
an optical sensor;
a shielding element; and
a commutation member, configured to move relative to the control assembly housing, wherein in response to movement of the commutation member relative to the control assembly housing, when the commutation member moves to different positions relative to the control assembly housing, the optical sensor is used for sensing changes in light reception at the different positions,
wherein the motor control module is operably connected to the optical sensor and is configured for controlling, by referring to the changes in the light reception output by the optical sensor, the electrical device to operate in any one of a forward operation mode and a reverse operation mode.

14. The non-contact control assembly for controlling operation of an electrical device according to claim 13, wherein the optical sensor comprises a photointerrupter.

15. The non-contact control assembly for controlling operation of an electrical device according to claim 13, wherein the optical sensor is mounted into the control assembly housing and the shielding element is mounted to the commutation member.

16. The non-contact control assembly for controlling operation of an electrical device according to claim 13, wherein forward operation and reverse operation of the electrical device comprise forward operation and reverse operation of a motor of the electrical device.

17. The non-contact control assembly for controlling operation of an electrical device according to claim 1, wherein the electrical device comprises at least one of an electric tool and an electric gardening tool.

18. An electrical switch, comprising the non-contact control assembly according to claim 1.
